(19) United States
(12) Patent Application Publication
(10) Pub. No.: US 2009/0238022 A1
(43) Pub. Date: Sep. 24, 2009

(54) SEMICONDUCTOR DEVICE AND CONTROLLING METHOD OF SEMICONDUCTOR DEVICE

(75) Inventor: Kiyohiro FURUTANI, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/410,045

(22) Filed: Mar. 24, 2009

(30) Foreign Application Priority Data
Mar. 24, 2008 (JP) P2008-075125

(51) Int. Cl. G11C 17/16; G11C 7/00

(52) U.S. Cl. 365/225.7; 365/189.011

(57) ABSTRACT

A semiconductor device includes: a setting circuit which sets a first setting value; a control circuit which receives a predetermined control signal and the first setting value so as to output a second setting value; and an output circuit which outputs a predetermined level in response to the first setting value or the second setting value, wherein the second setting value is changed from the first setting value based on the predetermined control signal.

### BACKGROUND OF THE INVENTION

1. Field of the Invention

The present invention relates to a semiconductor device and a method of controlling the semiconductor device which are suitable for a semiconductor integrated circuit in which chips are differently set by using a fuse element and the like.

Priority is claimed on Japanese Patent Application No. 2008-075125, filed Mar. 24, 2008, the content of which is incorporated herein by reference.

2. Description of Related Art

In a semiconductor integrated circuit such as a dynamic random access memory (DRAM), for example, as a countermeasure for deviation in the internal power source level of every resulting chip, the chips are individually adjusted and differently set by programming fuse elements shown in FIG. 1 according to the result of the adjustment.

FIG. 1 is a circuit diagram which is created by the inventor in order to explain the related art of the present application. A setting circuit 10 for setting 3-bit setting signals S2, S1, and S0, and a power circuit 20 for changing the power supply level by the setting signals S2, S1, and S0, are included. The setting circuit 10 includes memory circuits M1, M2, and M3, each of which includes a P-channel metal oxide semiconductor field-effect transistor (MOSFET) (hereinafter, refer to as a PMOS) 11, an N-channel MOSFET (hereinafter, refer to as a NMOS) 12, a fuse element 13, and inverters 14, 15, and 16. Each of the memory circuits M1, M2, and M3 memorizes (or fixes) a 1-bit setting value by destroying the fuse element 13 to be an open or a short circuit. In addition, the setting circuit 10 includes three composite gates 17, 18, and 19, which receive output fuse signals F2, F1, and F0 of the respective memory circuits M1, M2, and M3 or the like as input signals and output setting signals S2, Si, and S0.

In each of the memory circuits M1 to M3, a source node of the PMOS 11 is connected to a power source, and drain and gate nodes thereof are connected to drain and gate nodes of the NMOS 12, respectively. A source node of the NMOS 12 is connected to one end of the fuse element 13, and the other end of the fuse element 13 is connected to the ground. The inverter 14 and the inverter 15 cross-connect each input node and each output node so as to achieve a latch circuit, whose input node is connected to the drain nodes of the PMOS 11 and the NMOS 12 and output node is connected to the inverter 16. In addition, the output of the inverter 16 becomes the output fuse signal F2, F1, or F0 of the memory circuit M1, M2, or M3, which is determined by the state of the fuse element 13. With the configuration described above, when a reset signal/RESET is changed from the “L” level to the “H” level, the level of the fuse signal F2, F1, or F0 is set on the basis of the state of the fuse element 13.

On the other hand, the composite gates 17, 18, and 19 include a 2-input AND circuit which receives the fuse signal F2, F1, or F0 and the normal signal NORMAL, and a 2-input NOR circuit which receives the output of the AND circuit and the test mode signal T2, T1, or T0 and outputs the output setting signal S2, S1, or S0. Under normal operation, the inversed signals of the input fuse signals F2, F1, and F0 are output as the setting signals S2, S1, and S0 by setting the normal signal NORMAL to be the “H” level and by setting each of the test mode signals T2, T1, and T0 to be the “L” level. On the other hand, in trimming (that is, in adjusting), the inversed signals of the test mode signals T2, T1, and T0 are output as the setting signals S2, S1, and S0 by setting the normal signal NORMAL to be the “L” level and by setting each of the test mode signals T2, T1, and T0 to be the “H” level or the “L” level. Accordingly, in the power source circuit 20, the internal power source level is changed on the basis of the 3-bit input signals of the setting signals S2, S1, and S0.

That is, in trimming, while the normal signal NORMAL is set to be the “L” level and the test mode signals T2, T1, and T0 are switched to the “H” level or the “L” level, the internal power source level of the power circuit 20 is monitored. Then, when the internal power source level becomes a predetermined level, three fuse elements 13 are programmed on the basis of the levels of the test mode signals T2, T1, and T0. On the other hand, under normal operation, the setting signals S2, S1, and S0 are determined on the basis of the programmed state of three fuse elements 13 by setting the normal signal NORMAL to be the “H” level and by setting the test mode signals T2, T1, and T0 to be the “L” level. As a result, the power level of the power source circuit 20 is set.

In addition, there are disclosed techniques of a voltage adjusting method using the fuse elements and the counters (for example, refer to Japanese Unexamined Patent Application, First Publication, No. H5-265579 and No. 2007-42838).

However, in a semiconductor integrated circuit in which chips are programmed by using fuse elements shown in FIG. 1 or the like to have different setting values, when cause of defect in the semiconductor chip such as a DRAM chip is inspected because the DRAM chip is found that it is defective after the programmed products are released, the internal power source level may be changed from the current setting in some cases for the test of checking the state thereof. However, since the chips are different in the programmed state of the fuse element, it is necessary to differently input the test mode signals (T0 to T2) for every chip. For example, there is a need for reading setting states of the current fuse elements, that is, trimming information, which is a cumbersome operation, and thereby when a large number of chips are evaluated, there is a problem in that it takes much time for the evaluation.

### SUMMARY

The present invention seeks to solve one or more of the above problems, or to improve those problems at least in part.

In one embodiment, there is provided a semiconductor device that includes: a setting circuit which sets a first setting value; a control circuit which receives a predetermined control signal and the first setting value so as to output a second setting value; and an output circuit which outputs a predetermined level in response to the first setting value or the second setting value, wherein the second setting value is changed from the first setting value based on the predetermined control signal.

In another embodiment, there is provided a method of controlling a semiconductor device that includes a setting circuit which sets a setting value, and an output circuit which outputs a predetermined level in response to the setting value. The method includes: preparing a fuse element capable of being programmed to generate the setting value; setting the predetermined level; and changing the predetermined level in response to a programmed state of the fuse element and a test signal.

In another embodiment, there is provided a semiconductor device that includes: a plurality of fuse elements capable of having a programmed state; and an internal voltage generating circuit which outputs a variable voltage in response to the programmed state and a test signal input from outside.

In another embodiment, there is provided a semiconductor device that includes: a voltage generating circuit generating an internal voltage in response to control information supplied thereto; a register storing first information; a control circuit provided between the register and the voltage generating circuit, the control circuit operable to modify the first information to second information and supply the second information to the voltage generating circuit as the control information.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram that shows related art of the present invention;

FIG. 2 is a circuit diagram that shows a semiconductor device according to a first embodiment of the present invention;

FIG. 3 is a circuit diagram that shows a semiconductor device according to a second embodiment of the present invention; and

FIG. 4 is a block diagram that shows a semiconductor device according to a third embodiment of the present invention.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated here for explanatory purposes.

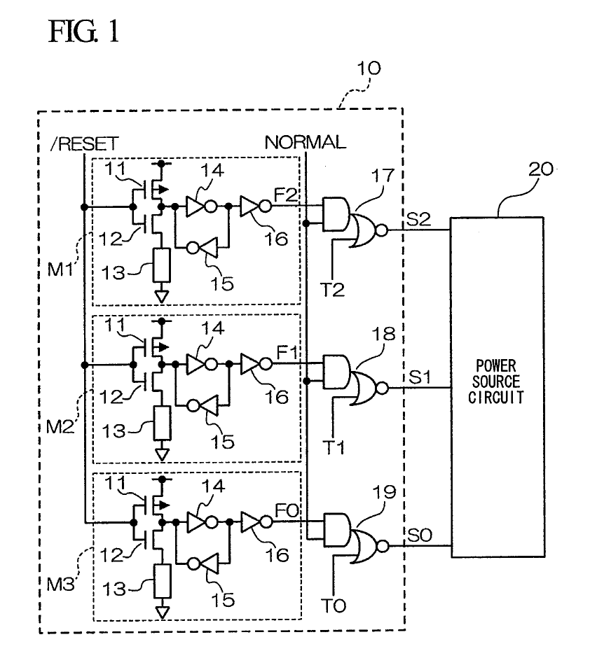

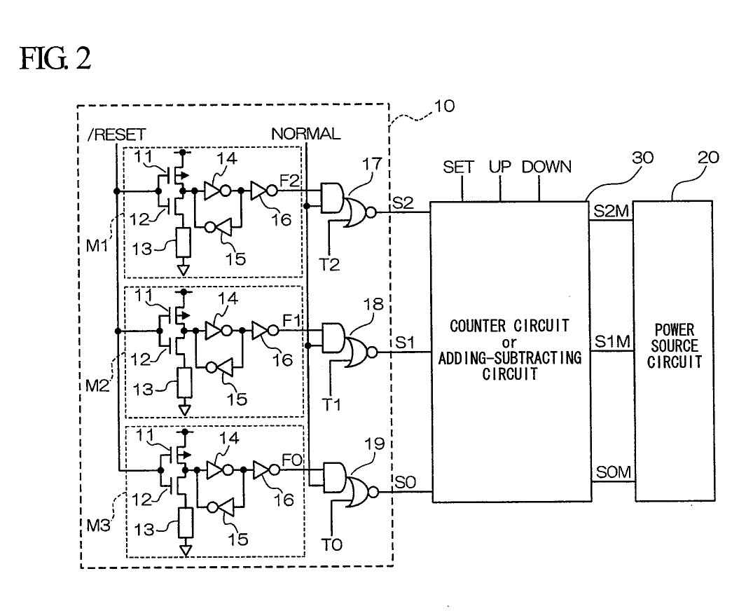

An embodiment of the present invention will be described hereinbelow with reference to the drawings. FIG. 2 is a circuit diagram showing a semiconductor device according to a first embodiment of the present invention. In FIG. 2, the same components as those in FIG. 1 are designated by the same reference symbols. Circuit blocks shown in FIG. 2 are mounted on, for example, a semiconductor chip such as a DRAM or the like. For example, various circuits included in a memory unit (not shown), pads used for performing an input/output operation of the chip with the outside, an input/output circuit and the like, are mounted on the semiconductor chip.

In the first embodiment shown in FIG. 2, compared with those shown in FIG. 1, it is different in that a counter circuit (or adding-subtracting circuit) 30 (hereinafter, refer to as a counter circuit) is inserted between the setting circuit 10 and the power source circuit 20. The counter circuit 30 includes an adding-subtracting circuit therein as a counter. In addition, the counter circuit 30 is a control circuit that receives 3-bit setting signals S2, S1, and S0 which represent setting values composed of a plurality of bits fixed by using a plurality of the fuse elements 13 in the setting circuit 10, a counter set signal SET as a control signal, an up signal UP, and a down signal DOWN. The counter circuit 30 outputs the resulting values of the setting signals S2, S1, and S0 when the setting signals S2, S1, and S0 are increased or decreased by a predetermined value corresponding to the control signal. In this case, when the counter set signal SET is in the “H” level, the counter circuit 30 outputs the received setting signals S2, S1, and S0 as they are as output setting signals S2M, S1M, and S0M. On the other hand, when the counter set signal SET is in the “L” level, the counter circuit 30 outputs the setting signals S2M, S1M, and S0M, each of which is increased by “1” as the up signal UP is toggled and decreased by “1” as the down signal DOWN is toggled, on the basis of values of the setting signals S2, S1, and S0 at the time when the counter set signal SET is changed from the “H” level to the “L” level (in this case, assuming that S2 is a 22 bit, S1 is a 21 bit, and S0 is a 20 bit).

To sum up the operations of the first embodiment of the present invention, the operations are as follows. (1) Before setting the fuse elements 13 (that is, before fuse-cutting, for example), the normal signal NORMAL is set to be the “L” level, the counter set signal SET is set to be the “H” level, the test mode signals (T0 to T2) are input to the power source circuit 20 as the setting signals S2M, S1M, and S0M, and the internal power source level is adjusted to a corresponding power source level. (2) Under normal operation, the normal signal NORMAL is set to be the “H” level, the test mode signals (T0 to T2) are set to be the “L” level, the counter set signal SET is set to be the “H” level, the trimming signals (inversion signals of the fuse signals F2 to F0) which are programmed to the fuse elements 13 are input to the power source circuit 20 as the setting signals S2M, S1M, and S0M, and the internal power source level is adjusted to a corresponding power source level. (3) In analyzing a defective device, the normal signal NORMAL is set to be the “H” level, the test mode signals (T0 to T2) are set to be the “L” level, the counter set signal SET is changed from the “H” level to the “L” level, the setting signals (S0M to S2M) which are shifted from the setting values for fuse information input to the counter circuit 30 according to the toggling times of the UP or DOWN signal are input to the power source circuit 20, and the internal power source level is adjusted to a corresponding power source level.

In addition, the various input signals, such as the normal signal NORMAL, the test mode signals T0 to T2, the counter set signal SET, the up signal UP, and the down signal DOWN, can be directly input via test pads provided on the semiconductor chip or can be set by inputting a predetermined command via the test pads or normal input/output pins.

According to the first embodiment, the counter circuit 30 as a control unit receives the counter set signal SET, the UP signal, and the DOWN signal as control signals, and outputs the 3-bit setting signals S2M, S1M, and S0M, which represent values that the setting values represented by the 3-bit setting signals S2, S1, and S0 fixed by the setting circuit 10, are increased or decreased. Therefore, without reading out a setting state of the 3-bit setting signals S2, S1, and S0 fixed by the setting circuit 10, that is, a setting state of three fuse elements 13, it is possible to change the setting signals S2M, S1M, and S0M received by the power source circuit 20 to a state shifted from the current fixed state. Accordingly, the output from the power source circuit 20 as an output circuit, that is, the power source level or the like can be set to perform a desired test.

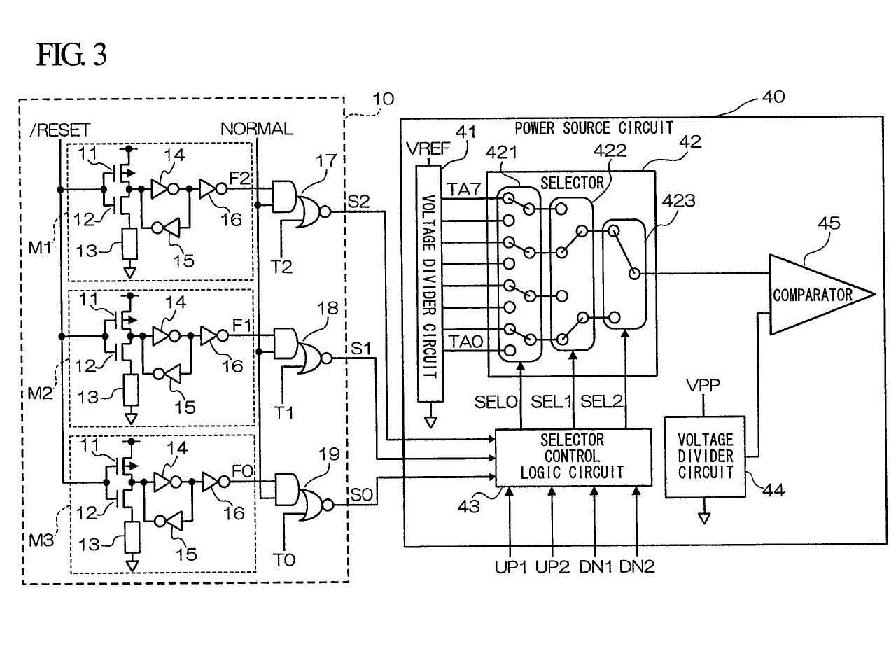

Next, FIG. 3 shows a semiconductor device according to a second embodiment of the present invention. In the second embodiment, the operation of the semiconductor device is controlled by a selector instead of the counting times of clocks to increase or decrease the power source from a set voltage according to the UP/DOWN signals (UP1, UP2, DN1, and DN2).

In the second embodiment shown in FIG. 3, the semiconductor device includes the same set circuit 10 as that shown in FIGS. 1 and 2, and a power source circuit 40. The power source circuit 40 receives the 3-bit setting signals S2, S1, and S0 output from the setting circuit 10 and selector control signals UPI, UP2, DN1, and DN2. The power source circuit 40 performs a control in which the predetermined setting signals S2, S1, and S0 are increased or decreased by a predetermined value according to the selector control signals UP1, UP2, DN1, and DN2 and outputs corresponding values. The power source circuit 40 includes a voltage divider circuit 41 for dividing a reference voltage VREF into 8 steps, a selector 42 for selecting one of 8 outputs of the voltage divider circuit 41, a selector control logic circuit 43 for controlling the selector 42 according to the setting signals S2, S1, and S0 and the selector control signals UP1, UP2, DN1, and DN2, a voltage divider circuit 44 for outputting a voltage which is generated by dividing the power source VPP by a predetermined voltage division ratio, and a comparator 45 for comparing a selected value of the selector 42 with a divided voltage value of the voltage divider circuit 44. The output of the comparator 45 is used for adjusting the internal power level by a predetermined circuit (not shown).

The selector 42 includes a selection unit 421 which has four 2-input 1-output selection circuits to select 4 outputs from 8 outputs of the voltage divider circuit 41, a selection unit 422 which has two 2-input 1-output selection circuits to select 2 outputs from 4 outputs of the selection unit 421, a selection unit 423 which has a one 2-input 1-output selection circuit to select 1 output from 2 outputs of the selection unit 422. In addition, the respective selection circuits of the selection unit 421, the selection unit 442, and the selection unit 423 determine selection values according to the levels of output signals SEL0, SEL1, and SEL2 of the selector control logic circuit 43, respectively. In this case, each selection circuit selects a high potential side at the “H” level, or a low potential side at the “L” level. For example, the state of the selection circuit shown in FIG. 3 shows that SEL0=“H”, SEL1=“L”, and SEL2=“H”.

In the configuration described above, (1) before cutting the fuses, the normal signal NORMAL becomes the “L” level, and the selector control signals UP1, UP2, DN1, and DN2 become the “L” level. When the selector control signals UP1, UP2, DN1, and DN2 are in the “L” level, the output signals SEL0, SEL1, and SEL2 of the selector control logic circuit 43 become the same levels as those of the setting signals S2, S1, and S0. Therefore, when the normal signal NORMAL is in the “L” level, the selector control signals (SEL0 to SEL2) are generated according to the test mode signals (T0 to T2), and the power source level is adjusted to a corresponding value. (2) Under normal operation, the normal signal NORMAL is in the “H” level and the test mode signals (T0 to T2) are in the “L” level, the selector control signals UP1, UP2, DN1, and DN2 are in the “L” level, the output signals SEL0, SEL1, and SEL2 of the selector control logic circuit 43 are generated according to the fuse signals F0 to F2, and the power source level is adjusted to a corresponding value. (3) In analyzing a defective product after being released, the normal signal NORMAL becomes the “H” level and the test mode signals (T0 to T2) become the “L” level, and any one of the selector control signals UP1, UP2, DN1, and DN2 becomes the “H” level. In this case, the setting values, which are represented by the setting signals S2, S1, and S0 according to the fuse signals F0 to F2, are set as a reference value (a divided voltage level as reference) under normal operation. Further, when any one of the selector control signals UP1, UP2, DN1, and DN2 becomes the “H” level, the corresponding output signals SEL0, SEL1, and SEL2 of the selector control logic circuit 43 are generated. Thereby, any one of the divided voltage levels, which is shifted from the reference value by “+1”, “+2”, “−1”, or “−2”, is selected, and thus the power source level is adjusted to a corresponding value.

The specific configuration of the selector control logic circuit 43 will be described hereinafter. Assuming that the outputs of the voltage divider circuit 41 shown in FIG. 3 are named TAP7 to TAP0 from the reference voltage VREF side (hereinafter, “/” shows a bar symbol (inversion symbol)), since a level of the signal SEL0 is changed when any one of TAP0 to TAP6 becomes a selected value (output value) and the signal UP1 becomes the “H” level or when any one of TAP1 to TAP7 becomes a selected value and the signal DN1 becomes the “H” level, the signal SEL0 is expressed as;

SEL0=S0×or {[UP1 and/(S0 and S1 and S2)] or [DN1 and (S0 or S1 or S2)]} (1),

where ‘/’ means inversion.

In addition, since a level of the signal SEL1 is changed when TAP3 is selected and the signal UP1 becomes the “H” level, when TAP4 is selected and the signal DN1 becomes the “H” level, when any one of TAP0 to TAP5 is selected and the signal UP2 becomes the “H” level, and when any one of TAP2 to TAP7 is selected and the signal DN2 becomes the “H” level, the signal SEL1 is expressed as;

$$SEL 1 = S 1 x or \{ \begin{matrix}\begin{matrix}\begin{matrix}( UP 1 and S 0 and S 1 and / S 2 ) \\ or ( DN 1 and / S 0 and / S 1 and S 2 )\end{matrix} \\ or [ UP 2 and / ( S 1 and S 2 ) ]\end{matrix} \\ or [ DN 2 and ( S 1 or S 2 ) ]\end{matrix} \} . \qquad ( 2 )$$

In addition, since a direction of the signal SEL2 is changed when TAP5 is selected and the signal DN2 becomes the “H” level, when TAP4 is selected and the signal DN1 becomes the “H” level, when TAP3 is selected and the signal UPI becomes the “H” level, and when TAP2 is selected and the signal UP2 becomes the “H” level, the signal SEL2 is expressed as;

$$SEL 2 = S 2 x or [ \begin{matrix}\begin{matrix}\begin{matrix}( DN 2 and S 0 and / S 1 and S 2 ) \\ or ( DN 1 and / S 0 and / S 1 and S 2 )\end{matrix} \\ or ( UP 1 and S 0 and S 1 and / S 2 )\end{matrix} \\ or ( UP 2 and / S 0 and S 1 and / S 2 )\end{matrix} ] . \qquad ( 3 )$$

The logics expressed by these equations may be applied among the signals SEL1, SEL2, and SEL3 and the signal S0, the signal S1, and the signal S2. In addition, it is a matter of course that the equations are not limited to the signals UP1 and UP2 and the signals DN1 and DN2, and the number of the signals may also be increased.

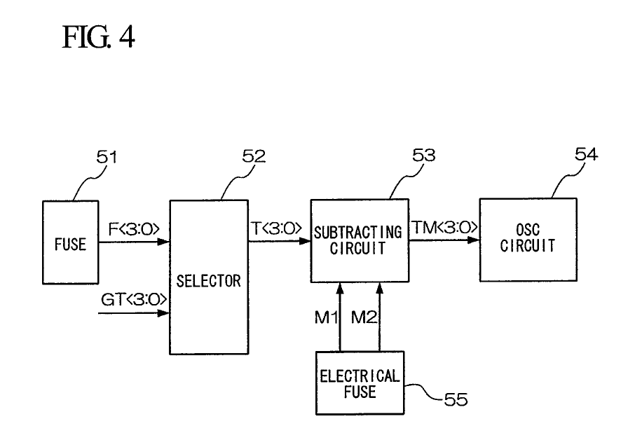

Next, FIG. 4 shows a semiconductor device according to a third embodiment of the present invention. In FIGS. 1 to 3, the output circuit, which performs the predetermined output according to the setting values fixed by the fuse elements 13, is the voltage generating circuit. However, in the third embodiment, the output circuit, which performs the predetermined output according to the setting values fixed by the fuse elements, is an oscillation circuit (OSC circuit). The oscillation circuit shifts an initial oscillation period set in advance according to the control signal. Further, in the third embodiment, in addition to the setting value, the control signals having an operation to increase or decrease the setting value by a predetermined value are also fixed by using the plurality of fuse elements.

FIG. 4 is a block diagram that shows the semiconductor device according to the third embodiment of the present invention. The circuit shown in FIG. 4 is mounted on the semiconductor chip having the oscillation circuit. On the semiconductor chip, for example, other various circuits, the pads for performing the input/output operation of the chip with the outside, and the input/output circuits, are mounted.

In the third embodiment shown in FIG. 4, the semiconductor device includes a fuse setting circuit 51 which has four fuse elements therein and outputs 4-bit signals F<3:0> fixed by the fuse elements, a selector 52 which selects either the signals F<3:022 or 4-bit signals GT<3:0> and outputs 4-bit signals T<3:0>, a fuse setting circuit 55 which has two fuse elements therein and outputs signals M1 and M2, each of which is composed of 1 bit and is fixed by the fuse element, a subtracting circuit 53 which subtracts the output signals M1 and M2 of 2 bits in total of the fuse setting circuit 55 from the 4-bit output signals T<3:0> of the selector 52, and an oscillation circuit 54 which changes the oscillation frequency according to 4-bit output signals TM<3:0> of the subtracting circuit 53. In the third embodiment, the subtracting circuit 53 includes the control circuit for generating a state shifted from the setting state in advance.

In the configuration shown in FIG. 4, the output F<3:0> of the fuse setting circuit 51 is programmed. When it is found that the complete product is defective, for example, in the data holding time test after the product is completed, it is possible to make the product to be good by outputting the signal M1 or M2 from the fuse setting circuit 55, in which the oscillation period is shifted from the initial period to a modified period corresponding to the signal M1 or M2, for example, “−1” or “−2” step of the modified period.

In addition, a fourth embodiment, which is the test method using the circuit in the first and second embodiments, will be described hereinafter. In the semiconductor memory, there may be performed a severe acceleration test where the potential of the word lines is lowered than the setting value. In this case, trimming codes for realizing a predetermined setting value are different for every chip. Therefore, if the same trimming code (hereinafter, refer to as a pseudo trimming code) for testing is uniformly used, the test is not severe for some chips because the voltage of the word line is higher that the predetermined value on the contrary. Then, the pseudo-trimming codes are set for every chip differently from each other such that the voltage is lower than the predetermined value, and then plural chips are tested at the same time. In this case, the test itself can be performed on the plural chips in parallel, but prior to the test, setting the pseudo trimming codes for every chip cannot be made in parallel, so that there is a problem in that the test time cannot be reduced even though the plural chips are tested at the same time.

For this reason, in the first and second embodiments described above, since the desired acceleration test may be performed on all the chips in the state where a test signal is generated in order to set a change amount for the setting value to “−1” or “−2” in the test after the fuse trimming, there is no need for a routine to set the pseudo trimming code for every chip. Accordingly, it is possible to prevent the test time of the acceleration test from increasing.

In the respective embodiments of the present invention described above, instead of reading current trimming information, it is possible to set the setting value in the state shifted from the current trimming state. Accordingly, a margin test can be performed on plural chips at the same time in the same test program, for example.

In addition, the embodiments of the present invention are not limited the configurations described above, and in addition to the voltage value or the frequency as the object amount for changing the output by the fixed setting value, the object amount is possible to be other analog values such as a current value or to be a digital value such as an initial value of the logic circuit. In addition, the number of bits of the setting value is not limited to that in the embodiments described above, and any number of bits may be possible as long as it is plural. In addition, the number of bits when the setting value is shifted can be suitably changed. In addition, the method of setting the fixed value is not limited to the fuse element using, for example, a wiring member, a transistor element or the like, and it is possible to use a nonvolatile memory circuit, which includes one or a plurality of transistors, or a read-only memory (ROM).

According to the present invention, the semiconductor device receives the predetermined control signals, and outputs the setting values which are fixed by a setting unit and are increased or decreased by a predetermined value corresponding to the control signal, and a predetermined output is performed from an output circuit according to the output of the resulting setting value. Therefore, without reading the fixed state of the setting value by the setting unit, it is possible to perform a desired test by setting the output of the output circuit for outputting a voltage or the like in a state shifted from the current fixed state. Accordingly, it is possible to easily perform a test such as an operation margin test which changes the setting value for semiconductor chips after setting differently for every chip by the fuse trimming.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor device comprising:
a setting circuit which sets a first setting value;
a control circuit which receives a predetermined control signal and said first setting value so as to output a second setting value; and
an output circuit which outputs a predetermined level in response to said first setting value or said second setting value,
wherein said second setting value is changed from said first setting value based on said predetermined control signal.

2. The semiconductor device according to claim 1, wherein said setting circuit holds said first setting value, which includes a plurality of bits, by using a fuse element.

3. The semiconductor device according to claim 1, wherein said control circuit increases or decreases said first setting value by a predetermined value based on said predetermined control signal, so as to generate said second setting value.

4. The semiconductor device according to claim 1, wherein:
said control circuit generates said second setting value by performing a logical operation between said first setting value and said predetermined control signal; and
said output circuit includes a selector which selects a second signal among from a plurality of first signals in response to said second setting value generated by said logical operation.

5. The semiconductor device according to claim 1, wherein:
said output circuit is a oscillation circuit; and
said control circuit shifts a oscillation period of said oscillation circuit based on said predetermined control signal.

6. The semiconductor device according to claim 2, wherein said predetermined control signal is held by said fuse element.

7. A method of controlling a semiconductor device including a setting circuit which sets a setting value, and an output circuit which outputs a predetermined level in response to said setting value, said method comprising:
preparing a fuse element capable of being programmed to generate said setting value;
setting said predetermined level; and
changing said predetermined level in response to a programmed state of said fuse element and a test signal.

8. A semiconductor device comprising:
a voltage generating circuit generating an internal voltage in response to control information supplied thereto;
a register storing first information;
a control circuit provided between said register and said voltage generating circuit, said control circuit operable to modify said first information to second information and supply said second information to said voltage generating circuit as said control information.

9. The semiconductor device according to claim 8, wherein said register includes a programmable fuse circuit outputting a fuse signal as said first information, and said fuse signal is capable of taking either first level or second level.

10. The semiconductor device according to claim 9, wherein said fuse signal takes said first level when said programmable fuse is being programmed, and said fuse signal takes said second level when said programmable fuse is not being programmed.

11. The semiconductor device according to claim 10, wherein said control circuit receives a control signal to modify said first information, and converts said fuse signal from said first level to said second level when said control signal is active, and does not convert when said control signal is inactive.

12. The semiconductor device according to claim 8, wherein said control circuit is further operable to supply said first information to said voltage generating circuit as said control information without modifying said first information.

13. The semiconductor device according to claim 12, wherein said control circuit converts said first information when said semiconductor device is in a test mode, and does not convert said first information when said semiconductor device is in a normal operation mode.
